(19) United States
(12) Patent Application Publication
(10) Pub. No.: US 2014/0049526 A1
(43) Pub. Date: Feb. 20, 2014

(54) DRIVING CIRCUIT AND DISPLAY APPARATUS HAVING THE SAME

(71) Applicant: SAMSUNG DISPLAY CO., LTD., Yongin-city (KR)

(72) Inventors: Ki-Hyun PYUN, Goyang-si (KR); Duk-Hwan KANG, Asan-si (KR); Seung-Woon SHIN, Asan-si (KR); Seok-Kun YOON, Seoul (KR); Myoung-Jun CHAI, Seoul (KR); Jong-Won CHOO, Seoul (KR)

(73) Assignee: SAMSUNG DISPLAY CO., LTD., Yongin-city (KR)

(21) Appl. No.: 13/738,522

(22) Filed: Jan. 10, 2013

(30) Foreign Application Priority Data
Aug. 14, 2012 (KR) 10-2012-0088749

(51) Int. Cl. G09G 5/00; H03K 3/01

(52) U.S. Cl. CPC G09G 5/003; H03K 3/01
USPC 345/205; 327/108

(57) ABSTRACT

A driving circuit including a timing control part, a driving voltage generating part, a voltage modifying part, and a slope control part. The voltage modifying part is configured to modify the gate-on voltage to a swing-on signal based on the kickback control signal, the swing-on signal including a slicing part, the slicing part including a falling portion during which a level of the swing-on signal falls from the first high level to a second high level lower than the first high level, and a rising portion during which the level of the swing-on signal rises from the second high level to the first high level. The slope control part is configured to decrease a slew rate of the rising portion in the swing-on signal and to output the swing-on signal decreased the slew rate of the rising portion as a gate-on signal.

### CROSS-REFERENCE TO RELATED APPLICATION

This application claims priority from and the benefit of Korean Patent Application No. 10-2012-0088749, filed on Aug. 14, 2012, which is hereby incorporated by reference for all purposes as if fully set forth herein.

### BACKGROUND

1. Field

Exemplary embodiments of the present invention relate to a driving circuit and a display apparatus having the driving circuit. More particularly, exemplary embodiments of the present invention relate to a driving circuit for increasing reliability and a display apparatus having the driving circuit.

2. Discussion of the Background

Generally, a liquid crystal display LCD apparatus has a relatively small thickness, light weight, and low power consumption, and thus the LCD apparatus is often used in monitors, laptop computers, cellular phones, etc. The LCD apparatus includes an LCD panel displaying images using a light transmittance of a liquid crystal, a backlight assembly behind the LCD panel and providing light to the LCD panel, and a driving circuit driving the LCD panel.

The LCD panel includes an array substrate including a gate line, a data line, a thin film transistor and a pixel electrode, an opposing substrate arranged opposite to the array substrate and including a common electrode, and a liquid crystal layer disposed between the array substrate and the opposing substrate. The driving circuit includes a timing control part generating a timing control signal, a gate driving part driving the gate line, and a source driving part driving the data line.

The source driving part includes a source flexible circuit board having a first end part connected to a long side of the LCD panel and a source circuit board connected to a second end part of the source flexible circuit board. The gate driving part includes a gate flexible circuit board having a first end part connected to a short side of the LCD panel and a gate circuit board connected to a second end part of the gate flexible circuit board.

The timing control part is mounted on a main circuit board, and the main circuit board is connected to the source and gate circuit boards through flexible circuit films. The source circuit board transfers a source control signal to a source driving chip mounted on the source circuit board through the flexible circuit film, and the gate circuit board transfers a gate control signal to a gate driving chip mounted on the gate circuit board through the flexible circuit film.

Currently, in order to decrease a size of the LCD, the gate circuit board has been omitted. By omitting the gate circuit board which transfers the gate driving signal, the gate driving signal is transferred to the gate flexible circuit board through the source flexible circuit board and signal lines formed on the LCD panel. The signal lines formed on the LCD panel transfer driving signals, and thus coupling noise is present in the driving signals transferred through the signals lines which are adjacent to each other.

### SUMMARY

Exemplary embodiments of the present invention provide a driving circuit capable of improving reliability of a driving signal.

Exemplary embodiments of the present invention also provide a display apparatus including the driving circuit.

Additional features of the invention will be set forth in the description which follows, and in part will be apparent from the description, or may be learned by practice of the invention.

An exemplary embodiment of the present invention discloses a driving circuit including a timing control part, a driving voltage generating part, a voltage modifying part, and a slope control part. The timing control part generates a kickback control signal which includes a control pulse repeated every 1 horizontal period. The driving voltage generating part is configured to generate a gate-on voltage at a first high level. The voltage modifying part is configured to modify the gate-on voltage to a swing-on signal based on the kickback control signal The swing-on signal includes a slicing part, and the slicing part includes a falling portion during which a level of the swing-on signal falls from the first high level to a second high level lower than the first high level, and a rising portion during which the level of the swing-on signal rises from the second high level to the first high level. The slope control part is configured to decrease a slew rate of the rising portion in the swing-on signal and output the swing-on signal having the decreased slew rate of the rising portion as a gate-on signal.

An exemplary embodiment of the present invention also discloses a display apparatus including a display panel and a main driving circuit. The display panel includes a display area in which a plurality of pixels is arranged and a peripheral area surrounding the display area, and a main driving circuit modifying the gate-on voltage to a swing-on signal based on the kickback control signal. The swing-on signal includes a slicing part, and the slicing part includes a falling portion where a level of the swing-on signal falls from a first high level to a second high level lower than the first high level and a rising portion where the level of the swing-on signal rises from the second high level to the first high level, decreasing a slew rate of the rising portion in the swing-on signal and outputting the swing-on signal decreased the slew rate of the rising portion as a gate-on signal, and a gate driving part generating a gate signal based on the gate-on signal and outputting the gate signal to the display panel.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a plan view illustrating a display apparatus according to an exemplary embodiment of the present invention.

FIG. 2 is a block diagram illustrating a main driving circuit as shown in FIG. 1.

FIG. 3 is a block diagram illustrating a gate voltage generating part as shown in FIG. 2.

FIG. 4 is a waveform diagram illustrating input and output signals of the gate voltage generating part as shown in FIG. 3.

FIG. 5 is a block diagram illustrating a gate driving part as shown in FIG. 1;

FIG. 6 is a waveform diagram illustrating input and output signals of a display driving circuit as shown in FIG. 1; and

FIG. 7A and FIG. 7B are waveform diagrams illustrating a gate clock signal coupled with a gate-on signal.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity Like reference numerals in the drawings denote like elements.

It will be understood that when an element or layer is referred to as being “on” or “connected to” another element or layer, it can be directly on or directly connected to the other element or layer, or intervening elements or layers may be present. In contrast, when an element or layer is referred to as being “directly on” or “directly connected to” another element or layer, there are no intervening elements or layers present. It will be understood that for the purposes of this disclosure, “at least one of X, Y, and Z” can be construed as X only, Y only, Z only, or any combination of two or more items X, Y, and Z (e.g., XYZ, XYY, YZ, ZZ).

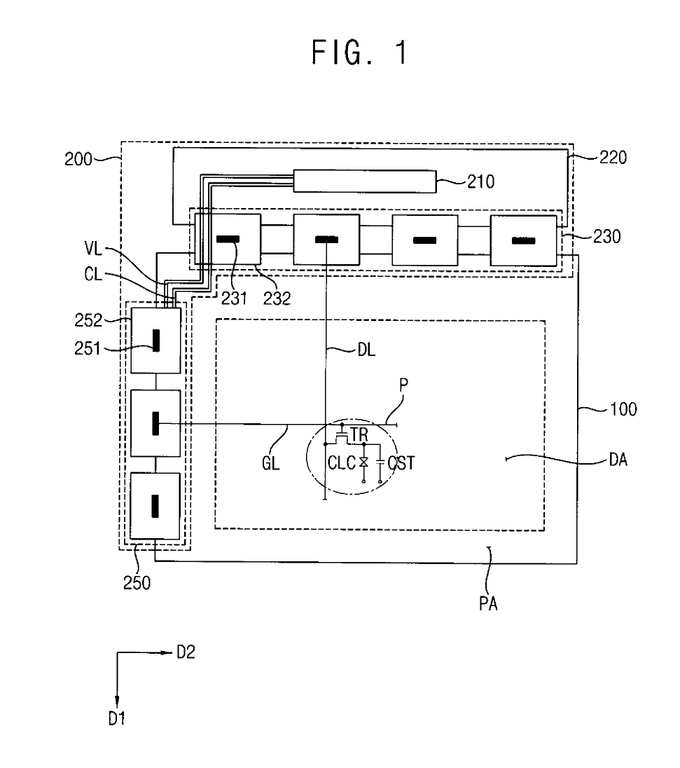

FIG. 1 is a plan view illustrating a display apparatus according to an exemplary embodiment of the present invention.

Referring to FIG. 1, the display apparatus may include a display panel 100 and a display driving circuit 200.

The display panel 100 may include a display area DA and a peripheral area PA surrounding the display area DA. A plurality of data lines DL, a plurality of gate lines GL, and a plurality of pixels P may be disposed in the display area DA.

The data lines DL may extend in a first direction D1. Alternatively, the data lines DL may be arranged in a second direction D2 substantially perpendicular to the first direction D1.

The gate lines GL may extend in the second direction D2. Alternatively, the gate lines DL may be arranged in the first direction D1.

The pixels P may be arranged in a matrix arrangement in the display area DA and display an image. Each pixel P may include a switching element TR, a liquid crystal capacitor CLC, and a storage capacitor CST. The switching element TR may be connected to the data line DL and the gate line GL. The liquid crystal capacitor CLC may be connected to the switching element TR, and the storage capacitor CST may be connected to the liquid crystal capacitor CLC.

The display driving circuit 200 may include a main driving circuit 210, a printed circuit board 220, a data driving part 230, and a gate driving part 250.

The main driving circuit 210 may control driving of the data driving part 230 and the gate driving part 250. For example, the main driving circuit 210 may provide the data driving part 230 with a data signal, a data control signal, and a power supply voltage. The data signal may include a color data signal and a correction data signal that performs correction using various algorithms such as an algorithm for improving a response time, an algorithm for improving white uniformity, etc. The data control signal may include a horizontal synchronization signal Hsync, a vertical synchronization signal Vsync, a load signal TP, etc, and the power source voltage may include a power supply voltage AVDD for an analog logic circuit and a power supply voltage DVDD for a digital logic circuit.

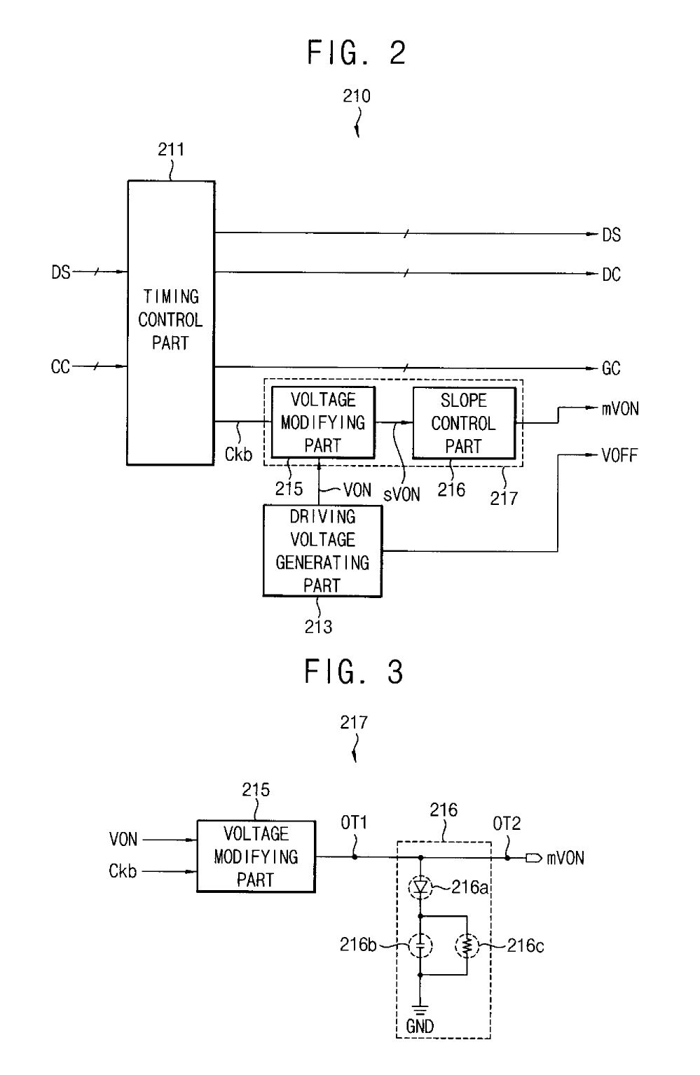

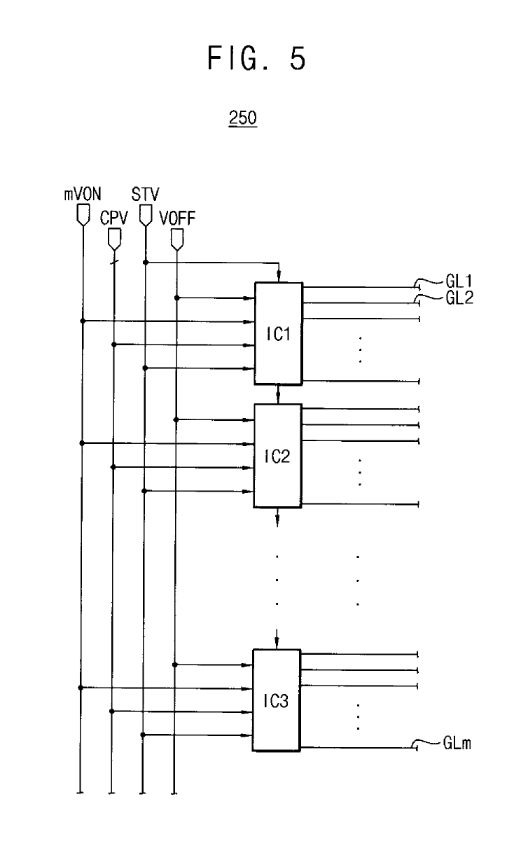

In addition, the main driving circuit 210 may provide the gate driving part 250 with a gate control signal, a gate-on signal mVON, and a gate-off voltage VOFF, as shown in FIG. 2. The gate control signal may include a start vertical signal STV, a gate clock signal CPV, etc, as shown in FIG. 5. The gate-on signal mVON may control a high level of the gate signal. The gate-off voltage VOFF may control a low level of the gate signal.

The main driving circuit 210 may be mounted on the printed circuit board 220.

The data driving part 230 may include a plurality of data flexible circuit boards 232, and a data driving chip 231 may be mounted on each data flexible circuit board 232. The data flexible circuit board 232 may electrically connect the printed circuit board 220 and the display panel 100. The gate control signals CPV and STV, the gate-on signal mVON, the gate-off voltage VOFF, etc outputted from the main driving circuit 210 may be transferred to the gate driving part 250 through the data flexible circuit board 232 adjacent to the gate driving part 250. For example, the gate control signals CPV and STV, the gate-on signal mVON and the gate-off voltage VOFF may be transferred to the gate driving part 250 through the leftmost data flexible circuit board 232, as shown in FIG. 1.

Therefore, a plurality of signal lines may be formed in the peripheral area PA of the display panel 100 to connect the data flexible circuit board 232 and the gate flexible circuit board 252 to each other. The gate control signal and the gate driving signal may be transferred through the signal lines. For example, the signal lines may include a clock line CL for transferring at least one gate clock signal CPV and a voltage line VL for transferring the gate-on signal mVON. Although not shown in the figures, the signal lines may transfer the start vertical signal STV, the gate-off voltage VOFF, etc.

The data driving chip 231 may output a data signal to the data lines DL of the display panel 100 based on the data control signal.

The gate driving part 250 may include a plurality of gate flexible circuit boards 252 and a gate driving chip 251 may be mounted on each gate flexible circuit board 252. The gate driving chip 251 may generate a gate signal using the gate control signals CPV and STV, the gate-on signal mVON, the gate-off voltage VOFF, etc, and sequentially output the gate signal to the gate lines GL of the display panel 100.

FIG. 2 is a block diagram illustrating a main driving circuit as shown in FIG. 1.

Referring to FIGS. 1 and 2, the main driving circuit 210 may include a timing control part 211, a driving voltage generating part 213, and a gate voltage generating part 217.

The timing control part 211 may receive a data signal DS and a timing control signal CC. The timing control part 211 may include various correction algorithms and correct the data signal using the various correction algorithms. The various correction algorithms may include an algorithm for improving the response time and an algorithm for improving the white uniformity. The timing control part 211 may generate a data control signal DC for controlling a driving timing of the data driving part 230 and a gate control signal GC for controlling a driving timing of the gate driving part 250. The timing control part 211 may provide the data driving part 230 with the data control signal DC and may provide the gate driving part 250 with the gate control signal GC.

In addition, the timing control part 211 may generate a kickback control signal Ckb and may provide the gate voltage generating part 217 with the kickback control signal Ckb. The kickback control signal Ckb may include a control pulse repeated every 1 horizontal period.

The driving voltage generating part 213 may generate a driving voltage. The driving voltage may include a gate-on voltage VON and a gate-off voltage VOFF. The gate-on voltage VON may have a first high level, and the gate-off voltage VOFF may have a low level.

The gate voltage generating part 217 may include a voltage modifying part 215 and a slope control part 216. The voltage modifying part 215 may modify the gate-on voltage

Von of a constant voltage to generate a swing-on signal sVON, which is swung every 1 horizontal period, based on the control pulse CP of the kickback control signal Ckb. The swing-on signal sVON may include a slicing part repeated every 1 horizontal period. The slicing part may include a falling portion in which a level of the swing-on signal sVON falls from the first high level to a second high level which is lower than the first high level and a rising portion in which the level of the swing-on signal sVON rises from the second high level to the first high level.

The slope control part 216 may control a slope of the slicing part in the swing-on signal sVON so that the slope of the slicing part in the swing-on signal sVON gradually reduces. The slope control part 216 may output the controlled swing-on signal sVON as the gate-on signal mVON. For example, the slope control part 216 may maintain a slew rate of the falling portion in the swing-on signal sVON, may decrease a slew rate of the rising portion in the swing-on signal sVON and then output the gate-on signal mVON. The slew rate may be defined as a voltage change per unit time.

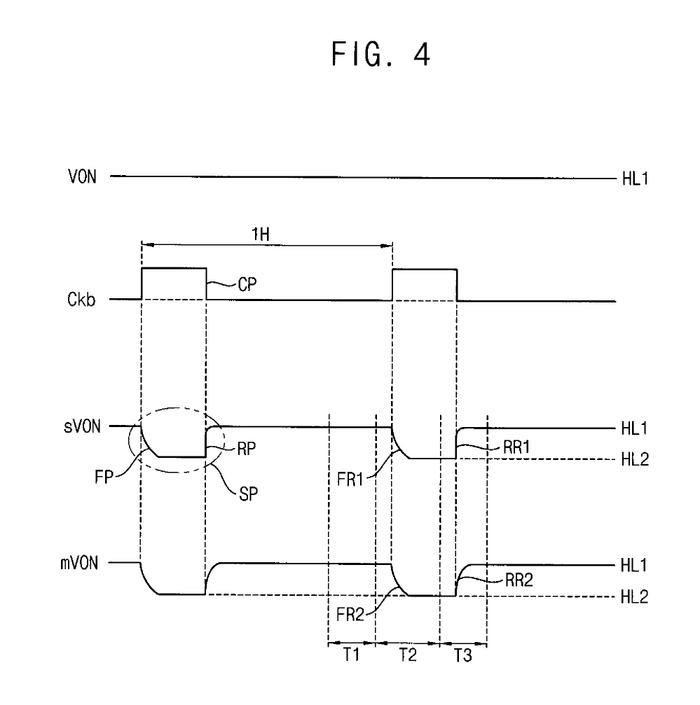

FIG. 3 is a block diagram illustrating a gate voltage generating part as shown in FIG. 2. FIG. 4 is a waveform diagram illustrating input and output signals of the gate voltage generating part as shown in FIG. 3.

Referring to FIG. 3, the gate voltage generating part 217 includes the voltage modifying part 215 and the slope control part 216.

The voltage modifying part 215 modifies the gate-on voltage Von to generate the swing-on signal sVON, which is swung every 1 horizontal period, based on the control pulse CP of the kickback control signal Ckb. The voltage modifying part 215 may be provided as a chip type, or a circuit type in which a plurality of elements is formed therein to be connected to each other. In addition, the voltage modifying part 215 may be provided as one chip which includes the slope control part 216.

The slope control part 216 includes a switching part 216a, a charging part 216b, and a resistor part 216c.

The switching part 216a includes a first terminal and a second terminal. The first terminal of the switching part 216a is connected to an output terminal OT1 of the voltage modifying part 215 and an output terminal OT2 of the slope control part 216. The second terminal of the switching part 216a is connected to the charging part 216b. The switching part 216a may be a diode, as shown in FIG. 3, or a transistor.

The charging part 216b includes a first terminal and a second terminal. The first terminal of the charging part 216b is connected to the switching part 216a. The second terminal of the charging part 216b is connected to a ground terminal GND.

The resistor part 216c includes a first terminal and a second terminal. The first terminal of the resistor part 216c is connected to both the switching part 216a and the charging part 216b. The second terminal of the resistor part 216c is connected to the charging part 216b and the ground terminal GND together.

Referring to FIGS. 3 and 4, the gate-on voltage VON is a constant voltage which has the first high level HL1. The kickback control signal Ckb is an alternating signal which includes the control pulse CP repeated every 1 horizontal period.

The voltage modifying part 215 outputs the swing-on signal sVON based on the gate-on voltage VON and the kickback control signal Ckb. The swing-on signal sVON includes a slicing part repeated every 1 horizontal period, in synchronization with the control pulse CP. The slicing part includes a falling portion FP in which a level of the swing-on signal sVON falls from the first high level HL1 to a second high level HL2 lower than the first high level HL1, and a rising portion RP in which the level of the swing-on signal sVON rises from the second high level HL2 to the first high level HL1. The falling portion FP of the swing-on signal sVON has a first falling slew rate FR1, and the rising portion RP of the swing-on signal sVON has a first rising slew rate RR1.

The slope control part 216 controls the first falling slew rate FR1 and the first rising slew rate RR1 to generate a second falling slew rate FR2 and a second rising slew rate RR2, respectively. The second falling slew rate FR2 is substantially the same as the first falling slew rate FR1 and the second rising slew rate RR2 is less than the first rising slew rate RR1.

For example, during a first period T1 where the swing-on signal sVON has the first high level HL1, the switching part 216a turns on and a voltage of the first high level HL1 is charged in the charging part 216b. Therefore, the voltage of the first high level HL1 is applied to the first terminal of the charging part 216b, and a voltage of the ground terminal GND is applied to the second terminal of the charging part 216b.

Then, during a second period T2 where the level of the swing-on signal sVON falls from the first high level HL1 to the second high level HL2, the switching part 216a turns off. Thereby, the voltage of the first high level HL1 charged in the charging part 216b is discharged through the ground terminal GND. Herein, the slope control part 216 does not operate as a load on the voltage modifying part 215. Therefore, an output signal of the voltage modifying part 215 is substantially the same as an output signal of the slope control part 216 so that the second falling slew rate FR2 may be maintained the same as the first falling slew rate FR1.

Then, during a third period T3 where the level of the swing-on signal sVON rises from the second high voltage HL2 to the first high voltage HL1, the switching part 216a turns on and the voltage of the first high level HL1 is charged in the charging part 216b.

The voltage of the first high level HL1 is charged in the charging part 216b so that the charging part 216b and the resistor part 216c operate as the load connected to the output terminal of the slope control part 216. A period during which the level of the output signal outputted from the voltage modifying part 215 rises from the second high level HL2 to the first high level HL1 may be increased by the charging part 216b and the resistor part 216c connected to the output terminal of the slope control part 216. Therefore, the second rising slew rate RR2 is less than the first rising slew rate RR1.

As a result, the slope control part 216 outputs the gate-on signal mVON having a rising slew rate less than the rising slew rate of the swing-on signal sVON.

When the voltage line transferring the gate-on signal is disposed adjacent the clock line transferring the gate clock signal CPV, a glitch may occur in the gate clock signal CPV as a result of the level transition of the gate-on signal having a relatively high level.

According to the present exemplary embodiment, the rising slew rate of the gate-on signal mVON is decreased by the slope control part 216 so that a glitch occurring in the gate clock signal CPV by coupling with the gate-on signal may be prevented or reduced.

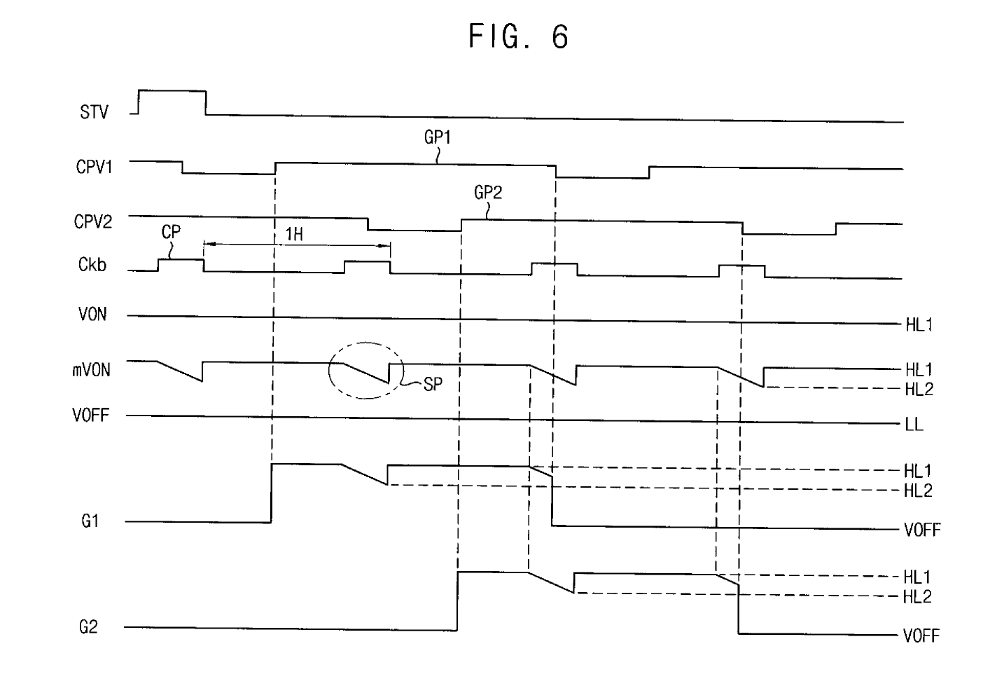

FIG. 5 is a block diagram illustrating a gate driving part as shown in FIG. 1. FIG. 6 is a waveform diagram illustrating input and output signals of a display driving circuit as shown in FIG. 1.

Referring to FIGS. 1 and 6, the timing control part 211 generates the kickback control signal Ckb, the start vertical signal STV, a first gate clock signal CPV1, and a second gate clock signal CPV2.

The kickback control signal Ckb includes the control pulse CP, and the control pulse CP is repeated every 1 horizontal period. The voltage modifying part 215 receives the kickback control signal Ckb.

The start vertical signal STV is a vertical synchronization signal and includes a pulse repeated every 1 frame.

The first gate clock signal CPV1 includes a first clock pulse GP1 which controls a high period of an odd-numbered gate signal. The first clock pulse GP1 is repeated every 2 horizontal periods. The second gate clock signal CPV2 includes a second clock pulse GP2 delayed by 1 horizontal period from the first clock pulse GP1. The second gate clock signal CPV2 is repeated every 2 horizontal periods. The second clock pulse GP2 controls the high period of an even-numbered gate signal. The second clock pulse CP2 partially overlaps with the first clock pulse GP1.

The first and second gate clock signals CPV1 and CPV2 are transferred to the gate driving part 250 through the data flexible printed circuit board 232 and the clock lines CL formed in the peripheral area PA of the display panel 100. The start vertical signal STV is transferred to the gate driving part 250 through the data flexible printed circuit board 232 and the signal line formed in the peripheral area PA of the display panel 100.

The driving voltage generating part 213 generates the gate-on voltage VON and the gate-off voltage VOFF. The gate-on voltage VON is the constant voltage having the first high level HL1, and the gate-off voltage VOFF is the constant voltage having the low level LL.

The driving voltage generating part 213 provides the voltage modifying part 215 with the gate-on voltage VON. The gate-off voltage VOFF is transferred to gate driving part 250 through the data flexible printed circuit board 232 and the signal line formed on the display panel 100.

The voltage modifying part 215 modifies the gate-on voltage VON to generate the swing-on signal sVON, which includes the slicing part SP having the second high level HL2 lower than the first high level HL1 based on the kickback control signal Ckb. The slicing part SP includes a falling portion FP and a rising portion RP. The falling portion FP has a first falling slew rate FR1, and the rising portion RP has a first rising slew rate RR1. The voltage modifying part 215 provides the slope control part 216 with the swing-on signal sVON.

The slope control part 216 controls the first falling slew rate FR1 so as to generate a second falling slew rate FR2 and controls the first rising slew rate RR1 so as to generate a second rising slew rate RR2. The second falling slew rate FR2 is substantially the same as the first falling slew rate RR1 and the second rising slew rate RR2 is less than the first rising slew rate RR1. The slope control part 216 output the gate-on signal mVON which includes the slicing part SP having the second falling slew rate FR2 and the second rising slew rate RR2.

The gate-on signal mVON is transferred to the gate driving part 250 through the data flexible printed circuit board 232 and the voltage line VL formed in the peripheral area PA of the display panel 100.

The gate driving part 250 includes a plurality of gate driving chips IC1, IC2, . . . , ICi, and the start vertical signal STV, the first and second gate clock signals CPV1 and CPV2, the gate-on signal mVON, and the gate-off voltage VOFF.

When the start vertical signal STV is applied to a first gate driving chip IC1, the gate driving chips IC2, . . , ICiare sequentially driven.

An odd-numbered gate driving chip controls the high period of an odd-numbered gate signal G1 based on a first clock pulse GP1 of the first gate clock signal CPV1, determines a gate high level of the odd-numbered gate signal G1 based on the gate-on signal mVON, and determines a gate low level of the odd-numbered gate signal G1 based on the gate-off voltage VOFF. In addition, an even-numbered gate driving chip controls the high period of an even-numbered gate signal G2 based on a second clock pulse GP2 of the second gate clock signal CPV2, determines the gate high level of the even-numbered gate signal G2 based on the gate-on signal mVON, and determines the gate low level of the even-numbered gate signal G2 based on the gate-off voltage VOFF.

A range of the gate high level may be the first high level HL1 to the second high level HL2 according to the slicing part SP in the gate-on signal mVON.

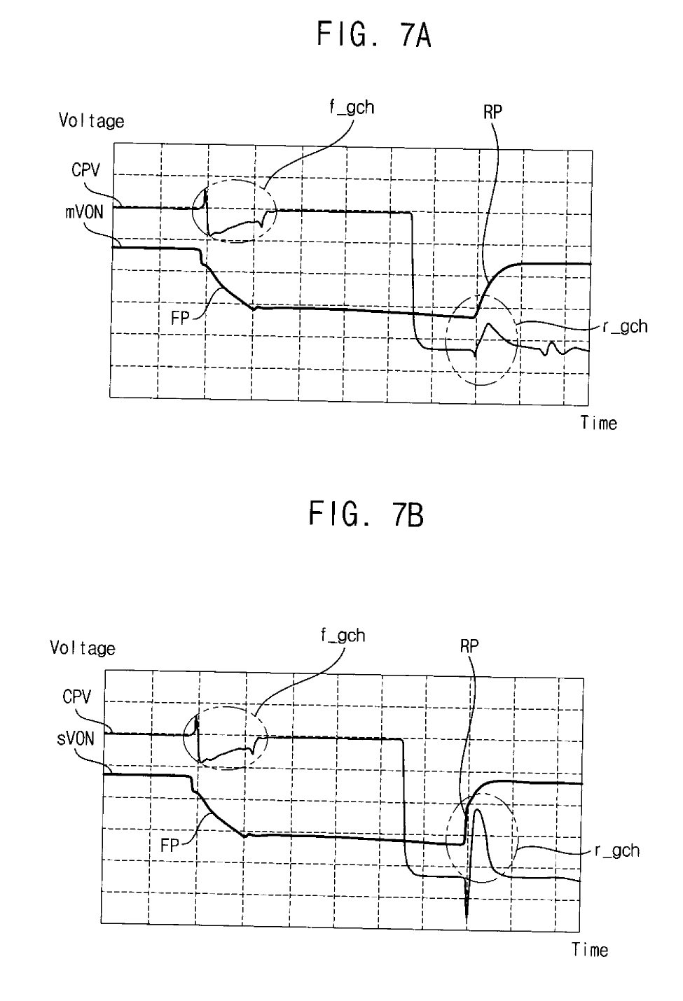

FIGS. 7A and 7B are waveform diagrams illustrating a gate clock signal coupled with a gate-on signal.

Referring to FIG. 7A, according to the present exemplary embodiment, the slope control part 216 controls the slope of the rising portion RP of the gate-on signal mVONso as to be gradually reduced such that the slew rate of the rising portion RP is decreased relatively by the slope control part 216.

Any glitch occurring as a result of the voltage transition of the gate-on signal mVON is included in the gate clock signal CPV transferred through the clock line, which is disposed adjacent to the voltage line transferring the gate-on signal mVON.

As shown in FIG. 7A, the gate clock signal CPV includes a falling glitch f_gch coupled with the falling portion FP of the gate-on signal mVON, and a rising glitch r_gch coupled with the rising portion RP of the gate-on signal mVON.

As described above, according to the present exemplary embodiment, a slope of the rising portion RP is controlled to be gradually reduced such that a level of the rising glitch r_gch coupled with the rising portion RP of the gate-on signal mVON is relatively decreased.

However, referring to FIG. 7B, the rising portion RP of the swing-on signal sVON outputted from the voltage modifying part 215 according to the present exemplary embodiment has a relatively steep slope.

When the gate-on signal applied to the voltage line of the display panel is the swing-on signal sVON, as shown in FIG. 7B, the glitch occurs in the gate clock signal CPV, which is transferred through the clock line adjacent to the voltage line, as a result of the voltage transition of the swing-on signal sVON.

As shown in FIG. 7B, the gate clock signal CPV includes the falling glitch f_gch coupled with the falling portion FP of the swing-on signal sVON, and the rising glitch r_gch coupled with the rising portion RP of the rising portion RP of the swing-on signal sVON.

In comparison with FIG. 7A, the rising portion RP in the swing-on signal sVON has a steep slope so that the rising glitch r_gch coupled with the rising portion RP of the swing-on signal sVON results in a relatively large discontinuity.

Therefore, as shown in the present exemplary embodiment above, the slew rate of the rising portion in the gate-on signal mVON is controlled to decrease so that the glitch of the gate clock signal CPV transferred through the signal line adjacent to the voltage line transferring the gate-on signal may be prevented or reduced. The gate clock signal CPV controls a charging rate of a pixel. Thus, the glitch of the gate clock signal CPV is prevented or reduced so that the display quality of the display apparatus may be improved.

The foregoing is illustrative of the present invention and is not to be construed as limiting thereof. Although a few exemplary embodiments of the present invention have been described, it will be apparent to those skilled in the art that various modifications and variations can be made in the present invention without departing from the spirit or scope of the invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific exemplary embodiments disclosed, and it is intended that the present invention cover the modifications and variations of this invention provided they come within the scope of the appended claims and their equivalents.

What is claimed is:

1. A driving circuit comprising:
a timing control part configured to generate a kickback control signal comprising a control pulse;
a driving voltage generating part configured to generate a gate-on voltage of a first high level;
a voltage modifying part configured to modify the gate-on voltage to generate a swing-on signal based on the kickback control signal, the swing-on signal comprising a slicing part, the slicing part comprising a falling portion during which a level of the swing-on signal falls from the first high level to a second high level lower than the first high level, and a rising portion during which the level of the swing-on signal rises from the second high level to the first high level; and
a slope control part configured to decrease a slew rate of the rising portion in the swing-on signal and output the swing-on signal having the rising portion with the decreased slew rate as a gate-on signal.

2. The driving circuit of claim 1, wherein the slope control part is configured to maintain a slew rate of the falling portion in the swing-on signal and to output the gate-on signal having a slew rate of the falling portion that is the same as the slew rate of the falling portion in the swing-on signal.

3. The driving circuit of claim 1, wherein the slope control part comprises:
a switching part connected to an output terminal of the voltage modifying part and an output terminal of the slope control part;
a charging part connected to the switching part and a ground terminal; and
a resistor part connected to the switching part and the charging part.

4. The driving circuit of claim 3, wherein the switching part comprises a diode.

5. The driving circuit of claim 3, wherein the charging part is configured to charge a voltage of the first high level during a first period where the level of the swing-on signal is the first high level when the switching part is turned on,
the charging part is configured to discharge the charged voltage during a second period where the level of the swing-on signal falls from the first high level to the second high level when the switching part is turned off, and
the charging part is configured to charge the voltage of the first high level when the level of the swing-on signal rises from the second high level to the first high level when the switching part is turned on.

6. The driving circuit of claim 1, wherein the timing control part is configured to generate at least one gate control signal and the driving voltage generating part is configured to generate a gate-off voltage of a low level.

7. The driving circuit of claim 6, further comprising:
a voltage line disposed in a peripheral area of a display panel and configured to transfer the gate-on signal, the display panel comprising a display area comprising a plurality of pixels, and the peripheral area surrounding the display area; and
a gate control line disposed in the peripheral area adjacent to the voltage line and configured to transfer the gate control signal.

8. The driving circuit of claim 7, wherein the gate control signal comprises a gate clock signal configured to control a high period of a gate signal having a level which is higher than the low level of the gate-off voltage.

9. The driving circuit of claim 8, further comprising:
a gate driving part configured to generate the gate signal based on the gate clock signal, the gate-on signal, and the gate-off voltage,
wherein the high period of the gate signal is determined by the gate clock signal, a gate high level is determined by the gate-on signal, and a gate low level is determined by the gate-off voltage.

10. A display apparatus comprising:
a display panel comprising a display area in which a plurality of pixels is arranged, and a peripheral area outside the display area;
a main driving circuit configured to modify a gate-on voltage to generate a swing-on signal based on a kickback control signal, the swing-on signal comprising a slicing part, the slicing part comprising a falling portion during which a level of the swing-on signal falls from a first high level to a second high level lower than the first high level, and a rising portion during which the level of the swing-on signal rises from the second high level to the first high level, thereby decreasing a slew rate of the rising portion in the swing-on signal and outputting the swing-on signal having the rising portion with the decreased slew rate as a gate-on signal; and
a gate driving part configured to generate a gate signal based on the gate-on signal and to output the gate signal to the display panel.

11. The display apparatus of claim 10, wherein the main driving circuit comprises:
a timing control part configured to generate a kickback control signal comprising a control pulse;
a driving voltage generating part configured to generate a gate-on voltage of a first high level;
a voltage modifying part configured to modify the gate-on voltage to generate a swing-on signal based on the kickback control signal, the swing-on signal comprising a slicing part, the slicing part comprising a falling portion during which a level of the swing-on signal falls from the first high level to a second high level lower than the first high level, and a rising portion during which the level of the swing-on signal rises from the second high level to the first high level; and
a slope control part configured to decrease a slew rate of the rising portion in the swing-on signal and to output the swing-on signal having the decreased slew rate of the rising portion as a gate-on signal.

12. The display apparatus of claim 11, wherein the slope control part is configured to maintain a slew rate of the falling portion in the swing-on signal and to output the gate-on signal having a slew rate of the falling portion that is the same as the slew rate of the falling portion in the swing-on signal.

13. The display apparatus of claim 11, wherein the slope control part comprises:
a switching part connected to an output terminal of the voltage modifying part and an output terminal of the slope control part;
a charging part connected to the switching part and a ground terminal; and
a resistor part connected to the switching part and the charging part.

14. The display apparatus of claim 13, wherein the switching part comprises a diode.

15. The display apparatus of claim 13, wherein the charging part is configured to charge a voltage of the first high level during a first period where the level of the swing-on signal is the first high level when the switching part turns on,
the charging part is configured to discharge the charged voltage during a second period where the level of the swing-on signal falls from the first high level to the second high level when the switching part turns off, and
the charging part is configured to charge the voltage of the first high level during which the level of the swing-on signal rises from the second high level to the first high level when the switching part turns on.

16. The display apparatus of claim 11, wherein the timing control part is configured to generate at least one gate control signal and the driving voltage generating part is configured to generate a gate-off voltage of a low level.

17. The display apparatus of claim 16, further comprising:
a voltage line disposed in a peripheral area of a display panel and configured to transfer the gate-on signal, the display panel comprising a display area comprising a plurality of pixels, the peripheral area surrounding the display area; and
a gate control line disposed in the peripheral area adjacent to the voltage line and configured to transfer the gate control signal.

18. The display apparatus of claim 17, further comprising:
a printed circuit board on which the main driving circuit is disposed;
a data flexible circuit board connected to the printed circuit board and the display panel;
a data driving chip disposed on the data flexible circuit board;
a gate flexible circuit board connected to the display panel; and
a gate driving chip disposed on the gate flexible circuit board,
wherein the voltage line and the signal line are connected to the data flexible circuit board and gate flexible circuit board.

19. The display apparatus of claim 18, wherein the signal line is configured to transfer a gate clock signal.

20. The driving circuit of claim 19, wherein the gate driving chip is configured to generate the gate signal based on the gate clock signal, the gate-on signal, and the gate-off voltage, and
wherein the high period of the gate signal is determined based on the gate clock signal, a gate high level of the gate signal is determined based on the gate-on signal, and a gate low level of the gate signal is determined based on the gate-off voltage.

21. The driving circuit of claim 1, wherein the control pulse is repeated every 1 horizontal period.

22. The display apparatus of claim 10, wherein the control pulse is repeated every 1 horizontal period.
